(19) United States
(12) Patent Application Publication
(10) Pub. No.: US 2025/0216336 A1
(43) Pub. Date: Jul. 3, 2025

(54) FAULT DETECTION AND CLASSIFICATION (FDC) FOR ENDPOINT DETECTION (EPD) BY REFLECTOMETRY

(71) Applicant: Tokyo Electron Limited, Tokyo (JP)

(72) Inventors: Colin PILCHER, Hillsboro, OR (US); Inga KUZNETSOVA, Fremont, CA (US); Jun SHINAGAWA, Fremont, CA (US); Masashi KANDA, Hillsboro, OR (US); Masaru NISHINO, Hillsboro, OR (US)

(73) Assignee: Tokyo Electron Limited, Tokyo (JP)

(21) Appl. No.: 18/402,328

(22) Filed: Jan. 2, 2024

(51) Int. Cl. G01N 21/88; G01N 21/95; H01L 21/66

(52) U.S. Cl. CPC G01N 21/8851; G01N 21/9501; H01L 22/12; G01N 2021/8874; G01N 2021/8887; G01N 2021/9511

(57) ABSTRACT

A method of endpoint detection includes receiving a wafer classification model that includes wafer types, product types and end-point detection (EPD) algorithms. Each EPD algorithm corresponds to a respective wafer type and a respective product type. Initial data of a wafer measured by an optical instrument are received. The wafer classification model is executed based on the initial data to determine a wafer type, a product type and an EPD algorithm for the wafer or to determine whether the wafer or the optical instrument is faulty. An etching process is executed on the wafer to obtain a product. The EPD algorithm is run to obtain an etching depth using data associated with the etching process so that an endpoint time of the etching process is determined by the etching depth or a maximum endpoint time. A post-etching outlier model is executed to determine whether the product is faulty.

### INCORPORATION BY REFERENCE

Aspects of the present disclosure are related to U.S. patent application Ser. No. 17/730,751 filed on Apr. 27, 2022 entitled “AUTONOMOUS OPERATION OF PLASMA PROCESSING TOOL”, U.S. patent application Ser. No. 17/025,651 filed on Sep. 18, 2020 entitled “VIRTUAL METROLOGY FOR WAFER RESULT PREDICTION”, and U.S. patent application Ser. No. 17/710,085 filed on Mar. 31, 2022 entitled “DATA FUSION OF MULTIPLE SENSORS”, all of which are incorporated herein by reference in their entirety.

### FIELD OF THE INVENTION

This disclosure relates generally to semiconductor fabrication and more specifically to film metrology.

### BACKGROUND

Device formation within microelectronic workpieces typically involves a series of manufacturing techniques related to the formation, patterning and removal of a number of layers of materials on a substrate. To meet the physical and electrical specifications of current and next generation semiconductor devices, various process flows are being developed to reduce feature size while maintaining structure integrity for various patterning processes. Many characterization techniques have therefore been developed for these process flow processes.

### SUMMARY

The present disclosure relates to a method of endpoint detection and an apparatus of executing the same.

According to a first aspect of the disclosure, a method of endpoint detection is provided. The method includes receiving a wafer classification model that includes wafer types, product types and end-point detection (EPD) algorithms. Each EPD algorithm corresponds to a respective wafer type and a respective product type. Initial data of a wafer measured by an optical instrument are received. The wafer classification model is executed based on the initial data to determine a wafer type, a product type and a EPD algorithm for the wafer or to determine whether the wafer or the optical instrument is faulty. An etching process is executed on the wafer to obtain a product. During the etching process, the EPD algorithm is run to obtain an etching depth using data associated with the etching process measured by sensors so that an endpoint time of the etching process is determined by the etching depth or a maximum endpoint time. A post-etching outlier model is executed to determine whether the product is faulty.

In some embodiments, when the wafer type, the product type and the EPD algorithm for the wafer are available in the wafer classification model, the wafer type, the product type and the EPD algorithm are determined for the wafer.

In some embodiments, when the wafer type, the product type and the EPD algorithm for the wafer are unavailable in the wafer classification model, the wafer or the optical instrument is determined to be faulty.

In some embodiments, an instrument diagnosis is executed to determine whether the optical instrument is faulty.

In some embodiments, when the optical instrument is faulty, a fault of the optical instrument is determined.

In some embodiments, when the optical instrument is not faulty, a fault of the wafer is determined by an incoming outlier model.

In some embodiments, when the product is faulty, whether an etching tool is faulty is determined based on an etching rate.

In some embodiments, when the etching tool is not faulty, an instrument diagnosis is executed to determine whether the optical instrument is faulty.

In some embodiments, when the optical instrument is not faulty, whether a reference wafer is faulty is determined.

In some embodiments, when the reference wafer is not faulty, the wafer is determined to be faulty prior to the etching process.

In some embodiments, an etching rate EPD algorithm is executed based on emission optical spectroscopy (OES) data and voltage-current (VI) data to obtain the etching rate.

In some embodiments, whether a structure of the wafer is uncovered by the etching process is determined using the data associated with the etching process.

In some embodiments, after the structure of the wafer is uncovered, the EPD algorithm is run to obtain the etching depth.

In some embodiments, the structure of the wafer includes a top of a transistor gate.

In some embodiments, when the etching depth reaches a target depth before the maximum endpoint time, the etching process is terminated when the target depth is reached.

In some embodiments, when the etching depth does not reach a target depth at the maximum endpoint time, the etching process is terminated at the maximum endpoint time.

In some embodiments, the initial data are normalized based on a reference wafer or an average of a plurality of wafers.

In some embodiments, the optical instrument includes a reflectometer.

In some embodiments, the initial data include reflectometry data, and the data associated with the etching process include emission optical spectroscopy (OES) data and reflectometry data.

According to a second aspect of the disclosure, an apparatus is provided. The apparatus includes a controller having a processor that is programmed to receive a wafer classification model that includes wafer types, product types and end-point detection (EPD) algorithm. Each EPD algorithm corresponds to a respective wafer type and a respective product type. Initial data of a wafer measured by an optical instrument are received. The wafer classification model is executed based on the initial data to determine a wafer type, a product type and an EPD algorithm for the wafer or to determine whether the wafer or the optical instrument is faulty. An etching process is executed on the wafer to obtain a product. During the etching process, the EPD algorithm is run to obtain an etching depth using data associated with the etching process measured by sensors so that an endpoint time of the etching process is determined by the etching depth or a maximum endpoint time. A post-etching outlier model is executed to determine whether the product is faulty.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 shows a diagram of a semiconductor process in accordance with some embodiments of the present disclosure.

FIG. 2 shows a diagram of a process of fault detection and classification (FDC) for in-situ reflectometer endpoint detection (EPD) in accordance with some embodiments of the present disclosure.

FIG. 3 shows a diagram of a process of FDC for an in-situ reflectometer system in accordance with some embodiments of the present disclosure.

FIG. 4 shows a diagram of a process of data fusion in accordance with some embodiments of the present disclosure.

FIG. 5 shows a diagram of a process of building a wafer classifier model in accordance with some embodiments of the present disclosure.

FIG. 6A shows normalized spectra in accordance with some embodiments of the present disclosure.

FIG. 6B shows a classifier result in accordance with some embodiments of the present disclosure.

FIG. 6C shows cross validation in accordance with some embodiments of the present disclosure.

FIG. 7A shows normalized spectra in accordance with some embodiments of the present disclosure.

FIG. 7B shows a classifier result in accordance with some embodiments of the present disclosure.

FIG. 7C shows cross validation in accordance with some embodiments of the present disclosure.

FIG. 8A shows impact of classification on EPD for different patterns in accordance with some embodiments of the present disclosure.

FIG. 8B shows impact of classification on EPD for different process steps in accordance with some embodiments of the present disclosure.

FIG. 9 shows a flow chart of a process of obtaining a film thickness in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

Key to many semiconductor flow processes is endpoint detection (EPD). Particularly, EPD reliability is critical in dry etch processes. Reflectometry is a simple technique, and yet reflectometry EPD is complex with many possible failure modes, making un-assisted troubleshooting difficult. No fault detection and classification (FDC) system for reflectometry currently exists. No dry etch in-situ reflectometer systems have been used for classification before.

Additionally, it is hard to meet the reflectometer EPD accuracy requirement without pattern-specific EPD configurations. Customers usually require plasma etch EPD solutions to be self-contained (e.g. not reliant on fab controller input). Information about the wafer pattern is not part of the plasma etch recipe, so the EPD system needs to be able to determine this information itself. For example in conventional technology, reflectometry without a classifier can be highly dependent on the wafer pattern/structure and pass/step.

Techniques herein utilize FDC to determine faults in, for example, three independent failure sources for EPD, including incoming wafer variations, etching rate (ER) variations that are too large to be compensated by EPD, and reflectometer system failures. As a result, manufacturability, in-situ performance and reliability of reflectometry EPD systems can be improved using FDC. System faults can be identified before they occur. Failures can be addressed with minimal input from engineers. System up time can be increased with the cost of operation reduced. Wafer patterns can be determined based on measurements taken by the reflectometry EPD system. Pre-etch measurement can be used for reflectometer FDC, improving system robustness.

Compared with existing techniques or practices, deployment of the EPD system in the present disclosure is simplified. Therefore, best possible EPD accuracy is achieved, and a pre-etch measurement system can enable other applications, such as FDC and etch rate monitoring.

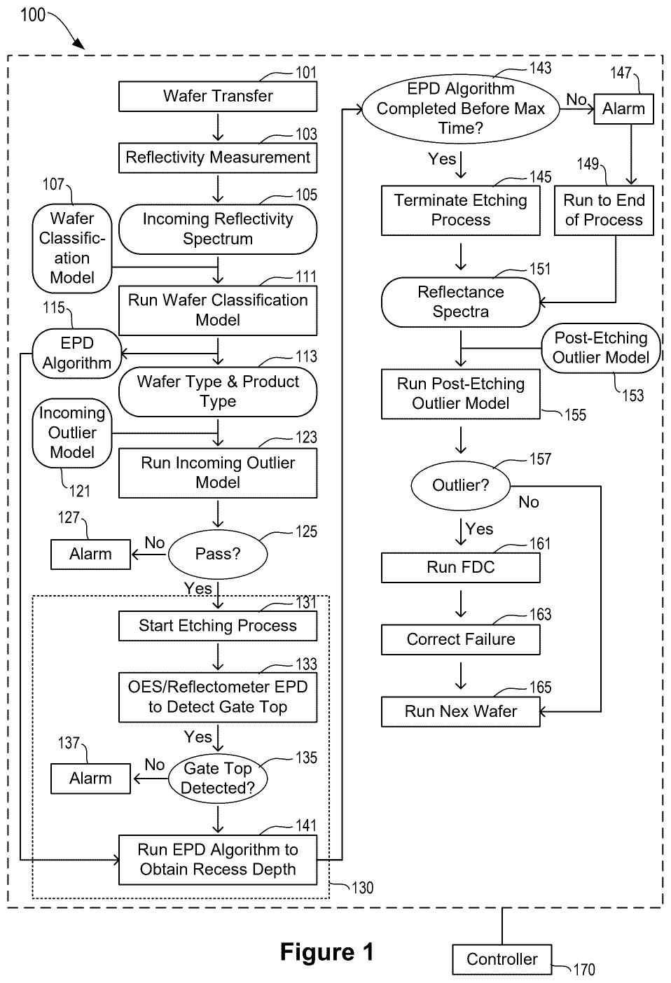

FIG. 1 shows a diagram of a semiconductor process (hereinafter referred to as a process 100) in accordance with some embodiments of the present disclosure. In box 101, a wafer is transferred to or loaded into a semiconductor tool such as an etching tool. Descriptions herein will be focused on dry etching for illustrative purposes, and it should be understood that techniques herein are applicable to other semiconductor processes as well.

In box 103, reflectivity measurement is conducted on the wafer to obtain an incoming reflectivity spectrum 105 that is used to run a wafer classification model 107 in box 111. The wafer classification model 107 can include information such as wafer types, product types and end-point detection (EPD) algorithms, and each EPD algorithm corresponds to a respective wafer type and a respective product type. For instance, wafer types can include information such as a wafer pattern of an incoming wafer which can characterized by the incoming reflectivity spectrum 105. Product types can include information such as what the wafer will become after the dry etching treatment, e.g. what pattern a corresponding product will have. The wafer classification model 107 can be configured to identify a corresponding wafer type and a corresponding product type (e.g. 113) of an incoming wafer based on the incoming reflectivity spectrum 105. Then, the wafer classification model 107 can be configured to select a corresponding EPD algorithm (e.g. 115) for the incoming wafer based on the corresponding wafer type and the corresponding product type (e.g. 113). The incoming reflectivity spectrum 105 and the wafer classification model 107 can be received from a third party or oneself, e.g. measured by an in-situ reflectometer of a corresponding etching tool.

In one embodiment, the EPD algorithm 115 can include a virtual metrology (VM) model. The VM model can be include an equation that calculates a critical dimension (CD), such as etching depth, on the wafer using reflectometer spectra as inputs for example. In another embodiment, the EPD algorithm 115 may be a conventional EPD algorithm that correlates reflectometer spectra with a change in wafer structure, without using virtual metrology methods. For instance, the EPD algorithm 115 may describe a wavelength range and a reflectivity value that indicates the target etching depth is reached, without modeling or predicting the depth outside of that range.

In box 123, an incoming outlier model 121 is executed to determine whether the wafer passes in oval 125. If not, an alarm is set off in box 127 and reported to a user. If yes, the process 100 proceeds to box 130 in which the EPD algorithm 115 is executed. Box 130 may begin with box 131 in which an etching process is started. During the etching process, data associated with the etching process, such as emission optical spectroscopy (OES) data and reflectometry data, are collected. The OES data and the reflectometry data can then be used to detect a top of a transistor gate in box 133.

In oval 135, if the top of the transistor gate is detected, meaning that the top of the transistor gate is uncovered by the etching process, the process 100 proceeds to box 141. Otherwise, an alarm is set off in box 137 and reported to a user. It should be understood that the top of the transistor gate is used for illustrative purposes only and that other structures (e.g. a specific material, a specific layer, a specific topography, etc.) of the wafer can be used as well.

In box 141, the EPD algorithm 115 is run to obtain an etching depth such as a recess depth. In oval 143, whether the EPD algorithm 115 is completed (e.g. whether a target depth is reached) before a maximum endpoint time is determined. If yes, the etching process is terminated when the target depth is reached. Otherwise, if the etching depth does not reach the target depth at the maximum endpoint time, an alarm is set off in box 147 and reported to a user. The process 100 proceeds to box 149 by running to an end of the etching process, e.g. terminating the etching process. In either case, a product and one or more reflectance spectra 151 are obtained.

It should be noted that boxes 131, 133, 135, 137 and 141 is one embodiment of box 130 for illustrative purposes. As discussed earlier, the EPD algorithm 115 can include a virtual metrology (VM) model having an equation or an algorithm without an equation. When the EPD algorithm 115 uses virtual metrology, then the optimal model (e.g. a corresponding VM model) will be determined by the wafer classification model 107 and sent to box 141. When the EPD algorithm 115 does not use virtual metrology, then the wafer classification model 107 will determine what other information is needed for the optimal EPD result. For example, this could be a specific wavelength range to use or a certain reflectivity value that indicates the target depth is reached. For the same reasons that different VM models are necessary, these kinds of values could vary between wafer/product types.

Particularly, the EPD algorithm 115 can be informed by the wafer classification model 107 to decide which EPD method to use (e.g. an equation versus an algorithm), which specific model (if any), whether or not to include a gate top detection step, and so on. In other words, the EPD algorithm 115 can include a plurality of embodiments (e.g. various VM equations and equation-less algorithms), and which embodiment of the EPD algorithm 115 is used for a specific wafer is determined by the wafer classification model 107, for example by analyzing the incoming reflectivity spectrum 105.

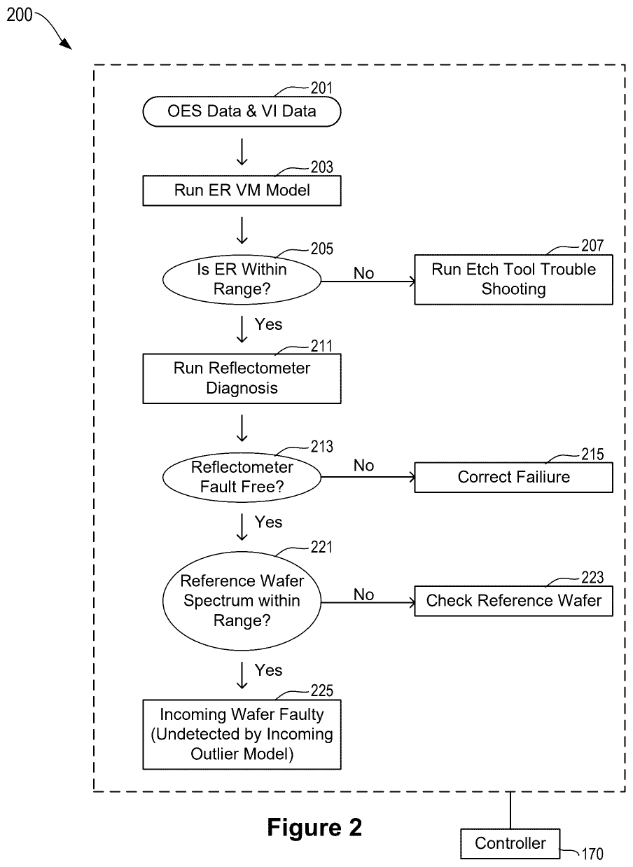

In box 155, a post-etching outlier model 153 is run to determine whether the product is an outlier in oval 157. If not, the process 100 proceeds to box 165 by running a next wafer. If yes, the process 100 proceeds to box 161 by running a failure detection and classification (FDC) model, which will be further explained in FIG. 2. In box 163, one or more failures are corrected.

FIG. 2 shows a diagram of a process 200 of fault detection and classification (FDC) for in-situ reflectometer endpoint detection (EPD) in accordance with some embodiments of the present disclosure. Data associated with the etching process, such as emission optical spectroscopy (OES) data and voltage-current (VI) data 201, can be used to run an etching rate (ER) EPD algorithm in box 203 to obtain an ER.

In oval 205, whether the ER is within a range is determined. When the ER is outside the range, the etching tool is faulty so an etching tool trouble shooting is run in box 207. When the ER is within the range, the process 200 proceeds to box 211 to run instrument diagnosis for the reflectometer. Table 1 below shows some examples of reflectometer FDC items.

TABLE 1
Examples of reflectometer FDC

| Fault | Cause | Detection | Solution | Info Needed |
|---|---|---|---|---|
| Angle of | Parts misaligned; | Perform | Perform | Calibration |
| Incidence | Wafer position | calibration | calibration | procedure; |
| (AOI) Shift | | | | Effect of AOI |
| (Mirror unit | | | | on spectrum |
| alignment) | | | | |
| Light Source | Power failure; | No/reduced | Repair/replace | Internal |
| | Diode laser | intensity | | monitoring of |
| | failure | | | light source |
| Window Age/ | Surface etching/ | ND Filter reached | Replace/adjust | None |
| Placement | deposition | maximum | window | |
| | | position | | |
| Neutral | Mechanical | Intensity cannot | Repair/replace | None |
| Density (ND) | failure | be adjusted | | |
| Filter | | within | | |
| | | operational range | | |
| Optical Cable | Mechanical | No/reduced | No/reduced | Fiber cable |
| | failure | intensity; | intensity; | specifications |
| | | Abnormal | Abnormal | |
| | | spectrum | spectrum | |
| Spectrometer | Defective | Abnormal dark | Repair/replace; | Calibration |
| | spectrometer; | signal; | Perform | procedure |
| | Mechanical | Wavelength shift | calibration | |
| | failure | | | |

Referring back to FIG. 2, in oval 213, whether the reflectometer is faulty is determined. If yes, one or more failures are corrected in box 215 for example using methods described in Table 1. When the reflectometer is not faulty, the process 200 proceeds to oval 221 to determine whether a reference wafer spectrum is within a range.

If the reference wafer spectrum is outside the range, the reference wafer is checked and determined to be faulty in box 223. If the reference wafer spectrum is within the range, the process 200 proceeds to box 225 in which the incoming wafer is determined to be faulty. In other words, the incoming wafer, prior to the etching process, had at least one faulty/defect that is undetected or undetectable by the incoming outlier model.

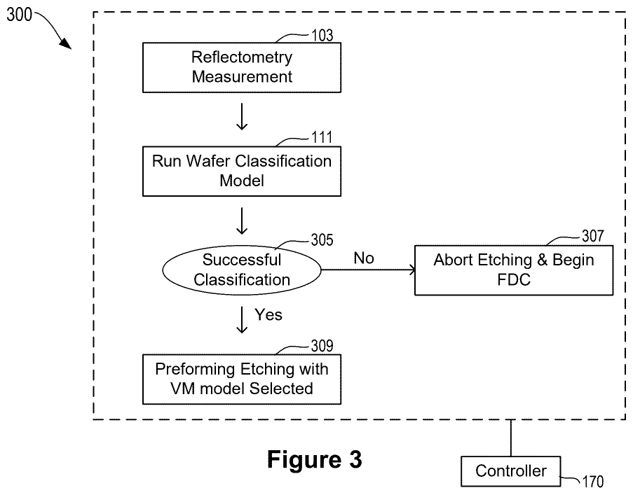

FIG. 3 shows a diagram of a process 300 of FDC for an in-situ reflectometer system in accordance with some embodiments of the present disclosure. After box 103 and box 111, whether classification is successful is determined in oval 305. If yes, the process 300 proceeds to box 309 by performing etching with the EPD algorithm 115 selected.

If classification is unsuccessful, the wafer does not belong to any of the wafer types in the wafer classification model 107. As a result, a corresponding wafer type, a corresponding product type and a corresponding EPD algorithm cannot be identified for the wafer. In other words, the wafer cannot be classified by the wafer classification model 107. Accordingly, the process 300 proceeds to box 307 in which etching is aborted and FDC is performed, for example using the process 200 in FIG. 2.

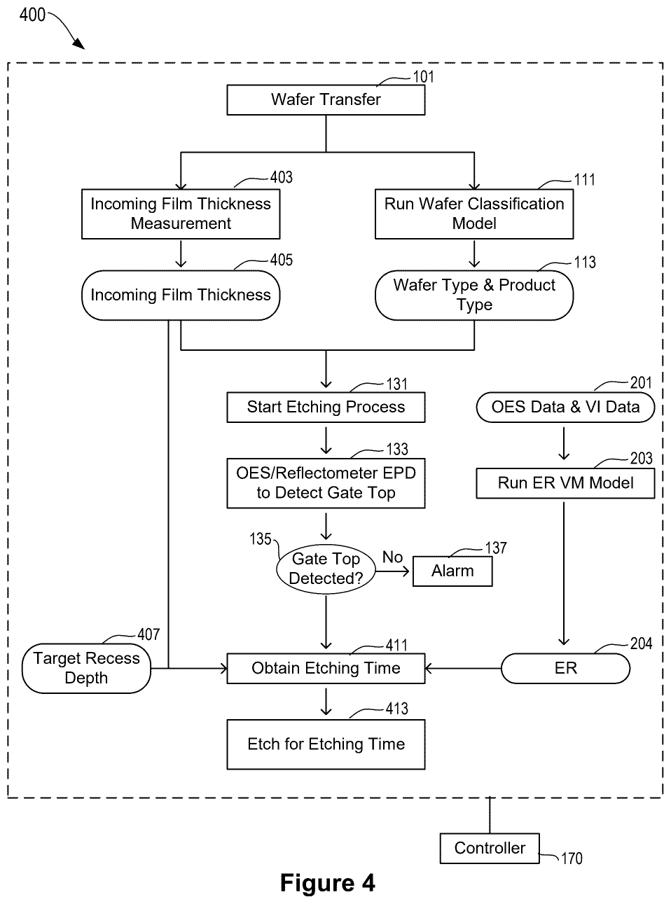

FIG. 4 shows a diagram of a process 400 of data fusion in accordance with some embodiments of the present disclosure. In box 403, an incoming film thickness 405 is measured before the etching process is started in box 131. An etching rate (ER) can be obtained from the ER EPD algorithm in box 203. In oval 135, when the top of the transistor gate is detected, the incoming film thickness 405, a target recess depth 407 and the ER 204 can be used to obtain an etching time for example by using techniques disclosed in Applicant's U.S. patent application Ser. No. 17/025,651 filed on Sep. 18, 2020 entitled “VIRTUAL METROLOGY FOR WAFER RESULT PREDICTION”, and U.S. patent application Ser. No. 17/710,085 filed on Mar. 31, 2022 entitled “DATA FUSION OF MULTIPLE SENSORS”, both of which are incorporated herein by reference in their entirety.

In other words, the etching time can be calculated when the incoming film thickness 405, the target recess depth 407 and the ER 204 are known. As a result, the etching process can be terminated based on the (calculated) etching time so that the etching process is executed for the duration of the etching time in box 413.

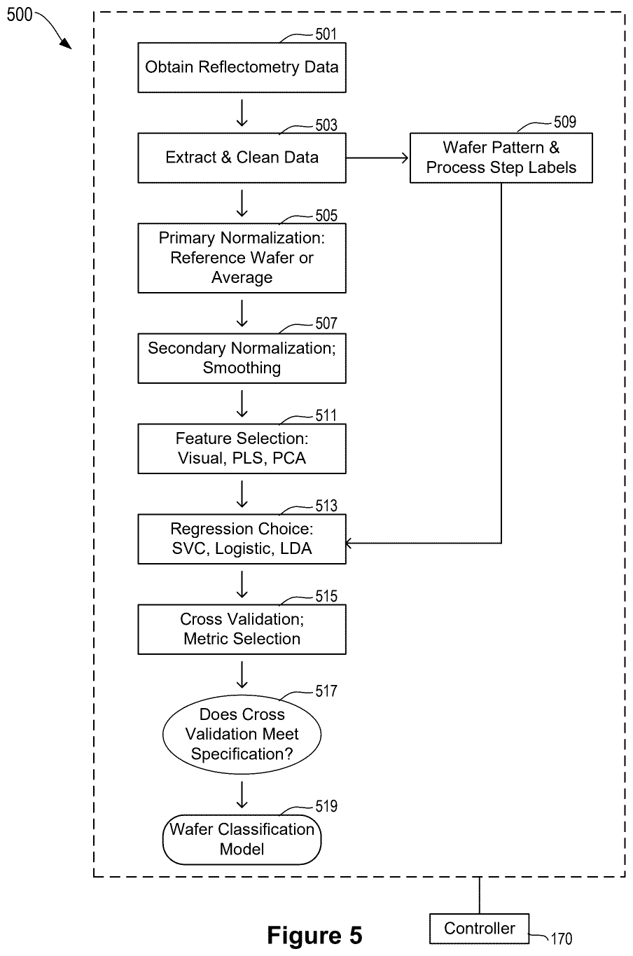

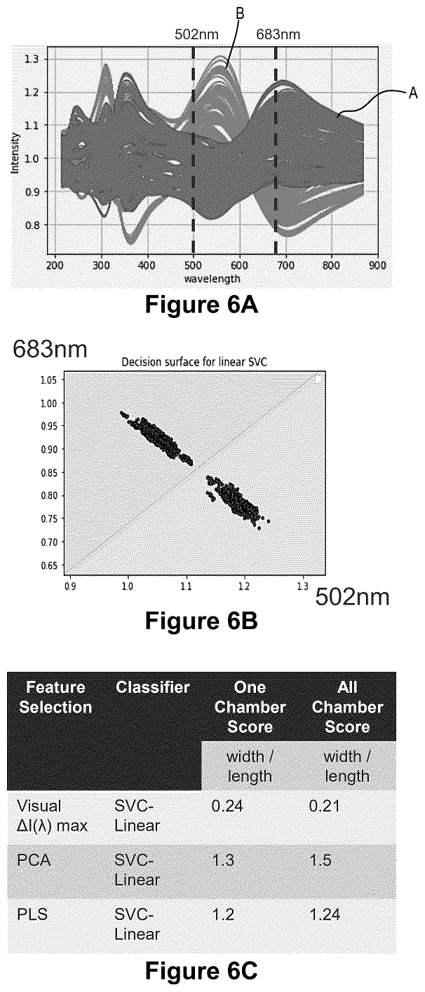

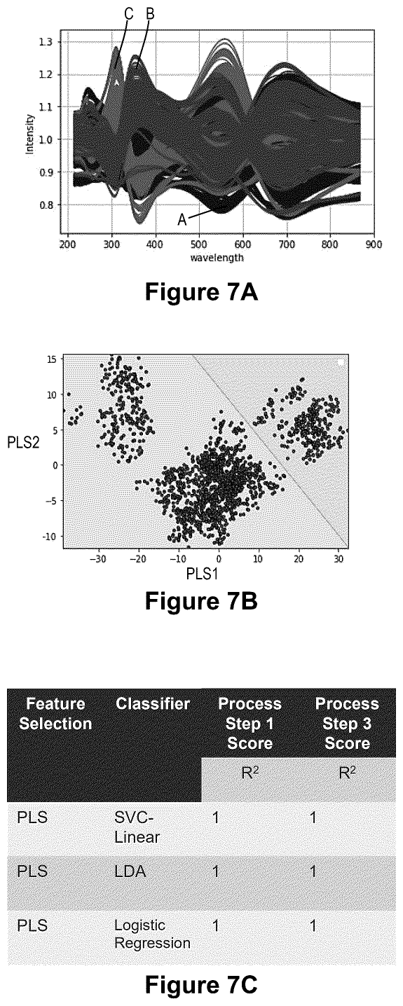

FIG. 5 shows a diagram of a process 500 of building a wafer classifier model (e.g. 107) in accordance with some embodiments of the present disclosure. In box 501, reflectometry data are obtained. The reflectometer may need to be intensity-compensated for long-term stability. In box 503, the reflectometry data are extracted from native file format and cleaned. In box 505, the reflectometry data go through a primary normalization over data of a reference wafer or an average of a plurality of wafers such as a mean of all wafers. In box 507, the reflectometry data go through a secondary normalization for smoothing. In box 509, the reflectometry data are used to determine a wafer pattern and process step labels. In box 511, feature selection is executed visually, by PLS (partial least squares), by PCA (principal component regression) or the like, which will be further explained in FIGS. 6A-6C and 7A-7C. In box 513, regression is executed by SVC (support vector classifiers), logistic regression, LDA (linear discriminant analysis) or the like. In box 515, cross validation is executed with metric selection. In oval 517, whether the cross validation meets specification is determined. If yes, a wafer classification model 519 is considered to be completed, and is ready to be used in the semiconductor process detailed in FIG. 1.

Further, a controller 170 may optionally be included in the examples of FIGS. 1, 2, 3, 4 and 5. Consider FIG. 1 for example. Components of a corresponding semiconductor tool can be connected to and controlled by the controller 170 that may optionally be connected to a corresponding memory storage unit and user interface (all not shown). Various semiconductor processing operations can be executed via the user interface, and various semiconductor processing recipes and operations can be stored in a storage unit. Accordingly, a given wafer can be processed within a chamber with various microfabrication techniques.

It will be recognized that the controller 170 may be coupled to various components of a corresponding etching tool to receive inputs from and provide outputs to the components. For example, the controller 170 can be configured to receive the incoming reflectivity spectrum 105 from an in-situ reflectometer of the etching tool. The controller 170 can also be configured to adjust knobs and control settings for the etching tool. Of course the adjustments can be manually made as well.

It will also be recognized that the controller 170 may be coupled to various components of the process 100 to receive inputs from and provide outputs to the components. For example, the controller 170 can be configured to receive a wafer type and a product type 113 and/or the EPD algorithm 115 from box 111. The controller 170 can further be configured to implement box 131, box 133, oval 135 and the like. For example, the controller 170 can implement boxes 101, 103 and 111 so that a user does not have to determine the wafer type and the product type 113 and/the EPD algorithm 115 manually for each wafer. Therefore, such a process can be automated without requiring input from an engineer or technician. Of course, one or more functions of the controller 170 can also be manually accomplished.

The controller 170 can be implemented in a wide variety of manners. In one example, the controller 170 is a computer. In another example, the controller 170 includes one or more programmable integrated circuits that are programmed to provide the functionality described herein. For example, one or more processors (e.g. microprocessor, microcontroller, central processing unit, etc.), programmable logic devices (e.g. complex programmable logic device (CPLD)), field programmable gate array (FPGA), etc.), and/or other programmable integrated circuits can be programmed with software or other programming instructions to implement the functionality of a proscribed plasma process recipe. It is further noted that the software or other programming instructions can be stored in one or more non-transitory computer-readable mediums (e.g. memory storage devices, FLASH memory, DRAM memory, reprogrammable storage devices, hard drives, floppy disks, DVDs, CD-ROMs, etc.), and the software or other programming instructions when executed by the programmable integrated circuits cause the programmable integrated circuits to perform the processes, functions, and/or capabilities described herein. Other variations could also be implemented.

It should be understood that descriptions above pertaining to the controller 170 in FIG. 1 are applicable to the controller 170 in FIGS. 2, 3, 4 and 5 as well. For instance, the controller 170 may be coupled to various components of the process 200, 300, 400 and/or 500 to receive inputs from and provide outputs to the components. Detailed descriptions will be omitted herein for simplicity purposes.

FIG. 6A shows normalized spectra of A and B. Two wavelengths such as 502 nm and 683 nm can be selected visually by a user. FIG. 6B shows a classifier result by decision surface for linear SVC (support vector classifiers) for 502 nm and 683 nm. FIG. 6C shows cross validation of visual selection, PCA (principal component regression) and PLS (partial least squares).

FIG. 7A shows normalized spectra of A, B and C. Similarly, one or more wavelengths can be selected visually by a user. FIG. 7B shows a classifier result by PLS. FIG. 7C shows cross validation of visual selection, PCA and PLS.

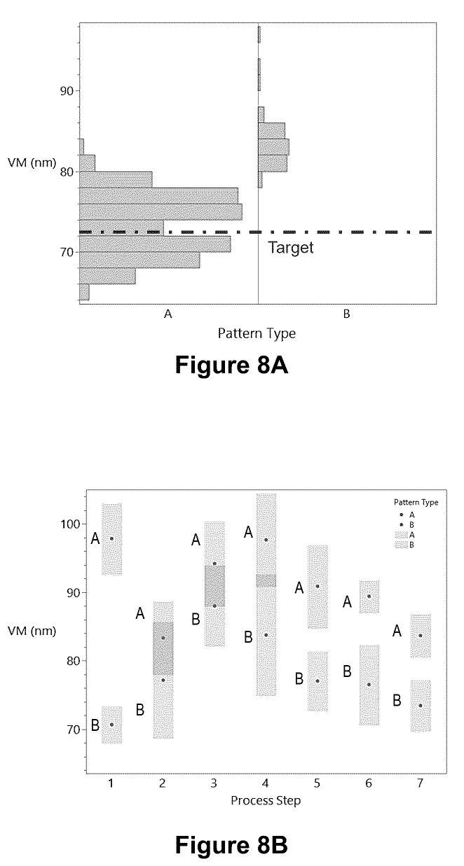

FIG. 8A shows impact of classification on EPD for pattern types A and B in accordance with some embodiments of the present disclosure. As can be seen, a model trained on product type “A” wafers may not be accurate for EPD type “B” wafers.

FIG. 8B shows impact of classification on EPD for different process steps in accordance with some embodiments of the present disclosure. As can be seen, a model trained on step 7 wafers has varying accuracy on other steps.

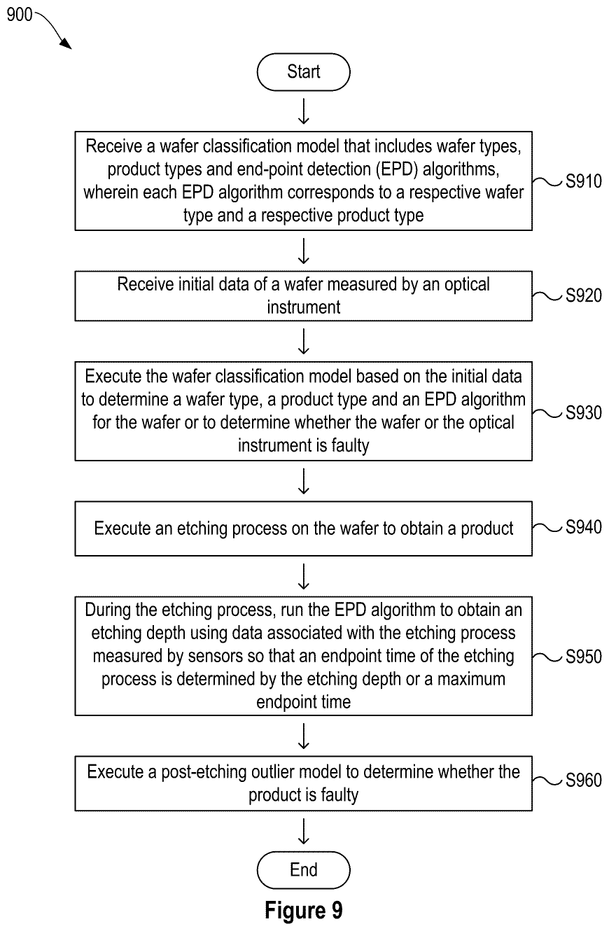

FIG. 9 shows a flow chart of a process 900 of endpoint detection in accordance with some embodiments of the present disclosure. At step S910, a wafer classification model (e.g. 107) is received that includes wafer types, product types and end-point detection (EPD) algorithms. Each EPD algorithm corresponds to a respective wafer type and a respective product type. At step S920, initial data (e.g. 105) of a wafer measured by an optical instrument are received. At step S930, the wafer classification model is executed based on the initial data to determine a wafer type, a product type and an EPD algorithm for the wafer or to determine whether the wafer or the optical instrument is faulty. At step S940, an etching process is executed on the wafer to obtain a product. At step S950, during the etching process, the EPD algorithm is run to obtain an etching depth using data associated with the etching process measured by sensors so that an endpoint time of the etching process is determined by the etching depth or a maximum endpoint time. At step S960, a post-etching outlier model is executed to determine whether the product is faulty.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of endpoint detection, the method comprising:
receiving a wafer classification model that includes wafer types, product types and end-point detection (EPD) algorithms, wherein each EPD algorithm corresponds to a respective wafer type and a respective product type;
receiving initial data of a wafer measured by an optical instrument;
executing the wafer classification model based on the initial data to determine a wafer type, a product type and an EPD algorithm for the wafer or to determine whether the wafer or the optical instrument is faulty;
executing an etching process on the wafer to obtain a product;
during the etching process, running the EPD algorithm to obtain an etching depth using data associated with the etching process measured by sensors so that an endpoint time of the etching process is determined by the etching depth or a maximum endpoint time; and
executing a post-etching outlier model to determine whether the product is faulty.

2. The method of claim 1, wherein:
when the wafer type, the product type and the EPD algorithm for the wafer are available in the wafer classification model, the wafer type, the product type and the EPD algorithm are determined for the wafer.

3. The method of claim 1, wherein:
when the wafer type, the product type and the EPD algorithm for the wafer are unavailable in the wafer classification model, the wafer or the optical instrument is determined to be faulty.

4. The method of claim 3, further comprising:
executing an instrument diagnosis to determine whether the optical instrument is faulty.

5. The method of claim 4, further comprising:
when the optical instrument is faulty, determining a fault of the optical instrument.

6. The method of claim 4, further comprising:
when the optical instrument is not faulty, determining a fault of the wafer by an incoming outlier model.

7. The method of claim 1, further comprising:
when the product is faulty, determining whether an etching tool is faulty based on an etching rate.

8. The method of claim 7, further comprising:
when the etching tool is not faulty, executing an instrument diagnosis to determine whether the optical instrument is faulty.

9. The method of claim 8, further comprising:
when the optical instrument is not faulty, determining whether a reference wafer is faulty.

10. The method of claim 9, further comprising:
when the reference wafer is not faulty, determining the wafer to be faulty prior to the etching process.

11. The method of claim 7, further comprising:
executing an etching rate EPD algorithm based on emission optical spectroscopy (OES) data and voltage-current (VI) data to obtain the etching rate.

12. The method of claim 1, further comprising:
determining whether a structure of the wafer is uncovered by the etching process using the data associated with the etching process.

13. The method of claim 12, further comprising:
after the structure of the wafer is uncovered, running the EPD algorithm to obtain the etching depth.

14. The method of claim 12, further comprising:
the structure of the wafer includes a top of a transistor gate.

15. The method of claim 1, further comprising:
when the etching depth reaches a target depth before the maximum endpoint time, terminating the etching process when the target depth is reached.

16. The method of claim 1, further comprising:
when the etching depth does not reach a target depth at the maximum endpoint time, terminating the etching process at the maximum endpoint time.

17. The method of claim 1, further comprising:
normalizing the initial data based on a reference wafer or an average of a plurality of wafers.

18. The method of claim 1, wherein:
the optical instrument comprises a reflectometer.

19. The method of claim 18, wherein:
the initial data include reflectometry data, and
the data associated with the etching process include emission optical spectroscopy (OES) data and reflectometry data.

20. An apparatus, comprising:
a controller including a processor that is programmed to:
receive a wafer classification model that includes wafer types, product types and end-point detection (EPD) algorithms, wherein each EPD algorithm corresponds to a respective wafer type and a respective product type;
receive initial data of a wafer measured by an optical instrument;
execute the wafer classification model based on the initial data to determine a wafer type, a product type and an EPD algorithm for the wafer or to determine whether the wafer or the optical instrument is faulty;
execute an etching process on the wafer to obtain a product;
during the etching process, run the EPD algorithm to obtain an etching depth using data associated with the etching process measured by sensors so that an endpoint time of the etching process is determined by the etching depth or a maximum endpoint time; and
execute a post-etching outlier model to determine whether the product is faulty.
